(19) United States
(12) Patent Application Publication
(10) Pub. No.: US 2026/0353641 A1
(43) Pub. Date: Nov. 5, 2026

(54) SEMICONDUCTOR STRUCTURE AND MANUFACTURING METHOD THEREOF

(71) Applicant: NANYA TECHNOLOGY CORPORATION, New Taipei City (TW)

(72) Inventors: Ming-Hung KAO, New Taipei City (TW); Ying-Cheng CHUANG, New Taipei City (TW); Yu HSIAO, New Taipei City (TW)

(21) Appl. No.: 19/198,119

(22) Filed: May 5, 2025

(51) Int. Cl. H10B 12/00

(52) U.S. Cl. CPC H10B 12/34; H10B 12/053

(57) ABSTRACT

The present disclosure provides a semiconductor structure and a manufacturing method thereof. The method includes forming a first trench in a substrate and forming a first gate structure in the first trench. The forming the first gate structure in the first trench includes the following operations. A first dielectric layer is deposited to cover an inner surface of the first trench. A first gate electrode is formed in the first trench and on the first dielectric layer. A second dielectric layer is deposited to cover the first gate electrode and the first dielectric layer. A portion of the second dielectric layer is etched to expose the first gate electrode. A third dielectric layer is deposited to cover the first gate electrode and the second dielectric layer. A second gate electrode is formed in the first trench and on the third dielectric layer.

### BACKGROUND

### Field of Invention

The present disclosure relates to a semiconductor structure and a manufacturing method thereof.

### Description of Related Art

Dynamic random access memory (DRAM) is a common semiconductor device. To pursue a higher integration density of the semiconductor device/DRAM, the dimension of the semiconductor device/DRAM gradually decreases. A buried gate structure becomes a mainstream technique used in DRAM in nowadays as the shrinkage of the dimension of DRAM. However, due to the short distance between the gate and the drain, the buried gate structure used in DRAM can easily cause gate induced drain leakage (GIDL). Therefore, it is urgent to develop a method to solve the aforementioned problem.

### SUMMARY

The present disclosure provides a method of manufacturing a semiconductor structure, in which the method includes forming a first trench in a substrate and forming a first gate structure in the first trench. Forming the first gate structure in the first trench includes the following operations. A first dielectric layer is formed to cover an inner surface of the first trench. A first gate electrode is formed in the first trench and on the first dielectric layer. A second dielectric layer is deposited in the first trench to cover the first gate electrode and the first dielectric layer. A portion of the second dielectric layer is etched to expose the first gate electrode. A third dielectric layer is deposited in the first trench to cover the first gate electrode and the second dielectric layer. A second gate electrode is formed in the first trench and on the third dielectric layer.

In some embodiments, the method further includes after forming the second gate electrode in the first trench, forming a plurality of doped regions in the substrate and on both sides of the second gate electrode.

In some embodiments, a thickness of the second dielectric layer is greater than a thickness of the third dielectric layer and a thickness of the first dielectric layer.

In some embodiments, a thickness of the first dielectric layer is between 2 nm and 3.8 nm, a thickness of the second dielectric layer is between 3 nm and 7 nm, and a thickness of the third dielectric layer is between 0.1 nm and 3 nm.

In some embodiments, a work function of the first gate electrode is different from a work function of the second gate electrode.

In some embodiments, the method further includes after forming the second gate electrode in the first trench, forming a capping layer in the first trench and on the second gate electrode to fill the first trench.

In some embodiments, the method further includes before forming the capping layer in the first trench and on the second gate electrode to fill the first trench, depositing a fourth dielectric layer to cover the second gate electrode and the second dielectric layer.

In some embodiments, a thickness of the fourth dielectric layer is between 0.1 nm and 3 nm.

In some embodiments, a height of the first gate electrode is between 80 nm and 90 nm, and a height of the second gate electrode is between 50 nm and 60 nm.

In some embodiments, the method further includes forming a second trench in an oxide layer in the substrate, in which forming the second trench in the oxide layer in the substrate and forming the first trench in the substrate are performed simultaneously; and forming a second gate structure in the second trench, in which forming the second gate structure in the second trench and forming the first gate structure in the first trench are performed simultaneously.

The present disclosure provides a semiconductor structure including a substrate and a gate structure embedded in the substrate. The gate structure includes a first gate electrode, a second gate electrode on the first gate electrode, a first dielectric layer disposed between the substrate and the first gate electrode and between the substrate and the second gate electrode, a second dielectric layer disposed between the first dielectric layer and the second gate electrode, and a third dielectric layer disposed between the second dielectric layer and the second gate electrode and between the first gate electrode and the second gate electrode, in which a material of the second dielectric layer is different from a material of the third dielectric layer.

In some embodiments, the material of the second dielectric layer is different from a material of the first dielectric layer.

In some embodiments, a thickness of the second dielectric layer is greater than a thickness of the third dielectric layer and a thickness of the first dielectric layer.

In some embodiments, a thickness of the first dielectric layer is between 2 nm and 3.8 nm, a thickness of the second dielectric layer is between 3 nm and 7 nm, and a thickness of the third dielectric layer is between 0.1 nm and 3 nm.

In some embodiments, the semiconductor structure further includes a plurality of doped regions disposed in the substrate and on both sides of the second gate electrode.

In some embodiments, the semiconductor structure further includes a capping layer disposed on the second gate electrode.

In some embodiments, the semiconductor structure further includes a fourth dielectric layer disposed between the third dielectric layer and the capping layer and between the second gate electrode and the capping layer.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings.

FIG. 1A is a flow diagram of a method of forming a semiconductor structure, in accordance with various embodiments.

FIG. 1B is a flow diagram of a method of forming gate structures, in accordance with various embodiments.

FIGS. 2-16 are cross-sectional views illustrating intermediate stages of forming a semiconductor structure, in accordance with various embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

It is appreciated that although the terms “first,” “second,” “third,” etc., may be used in this document to describe different components, parts, regions, and/or layers, such components, parts, regions, and/or layers shall not be limited by these terms. These terms are used only to distinguish a component, part, region, or layer from another component, part, region, or layer. Therefore, the “first element,” “component,” “region,” or “layer” discussed below may be referred to as a second element, component, region, or layer without departing from the teachings herein.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate.

The semiconductor structure of the present disclosure includes a gate structure with a thick dielectric layer on its sidewall, such that the semiconductor structure may mitigate GIDL effects.

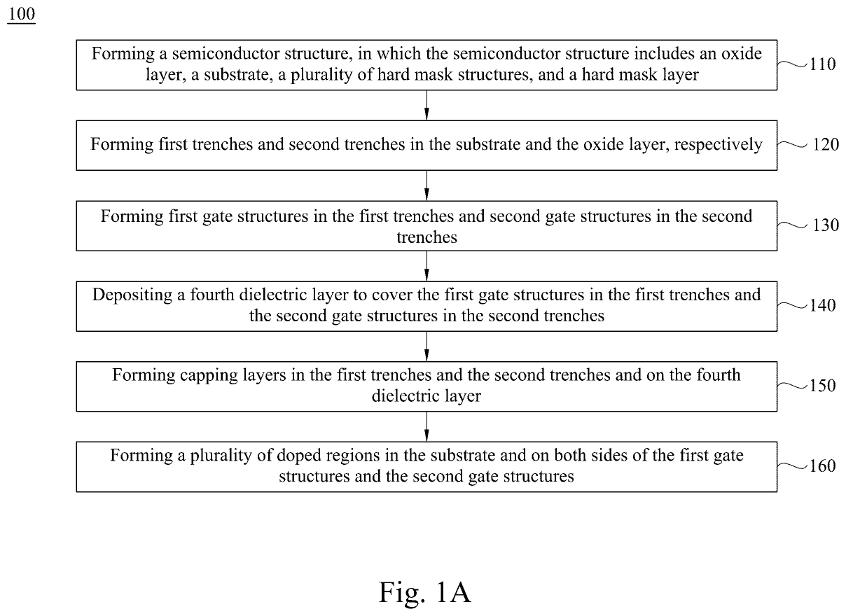

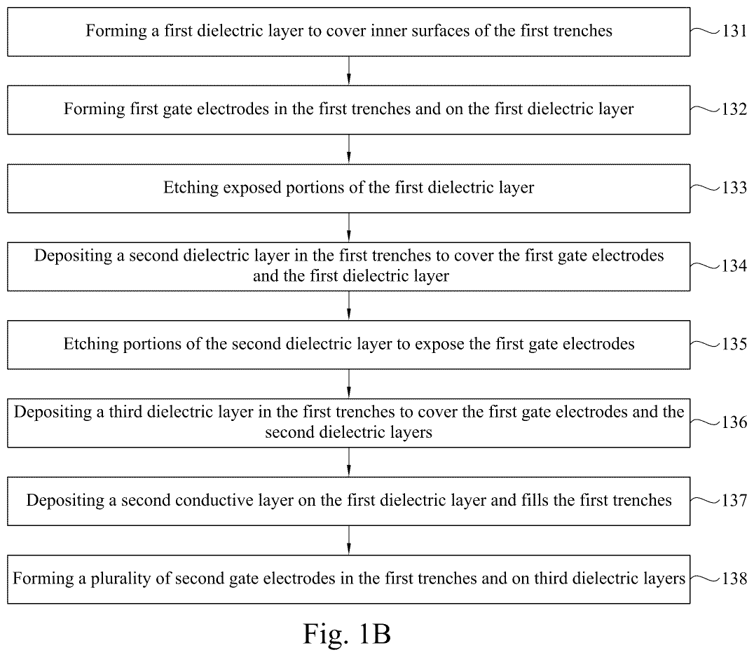

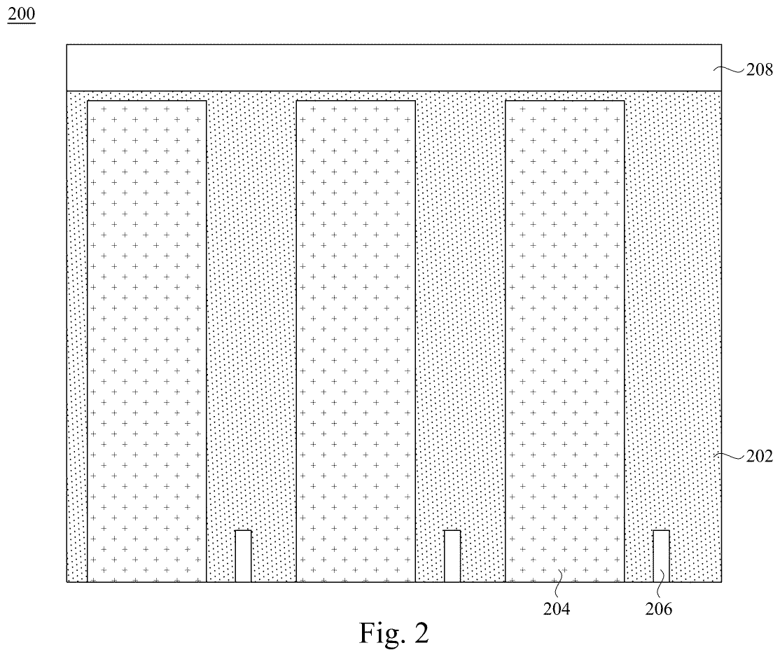

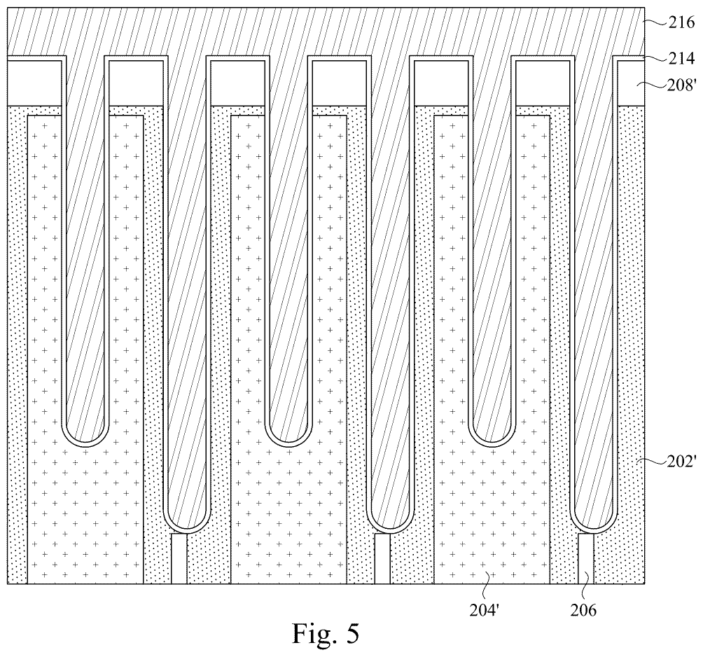

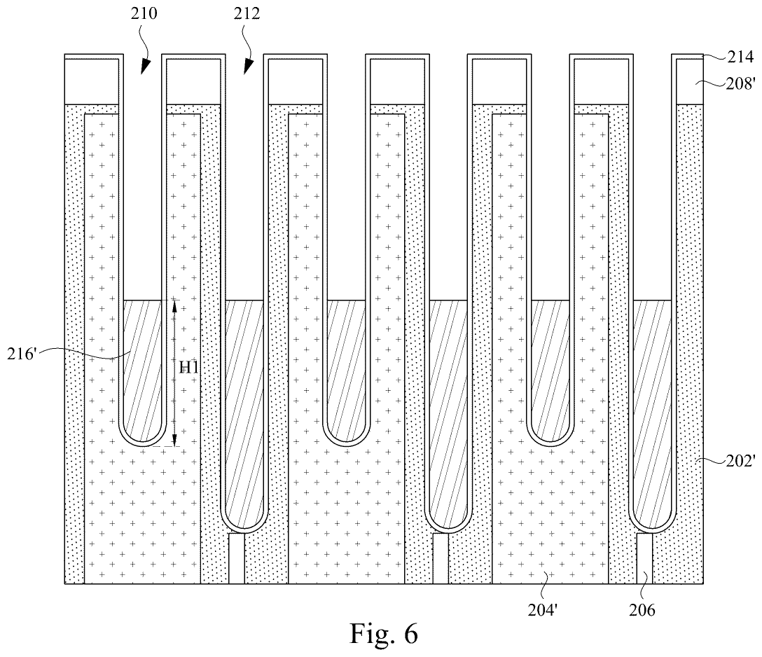

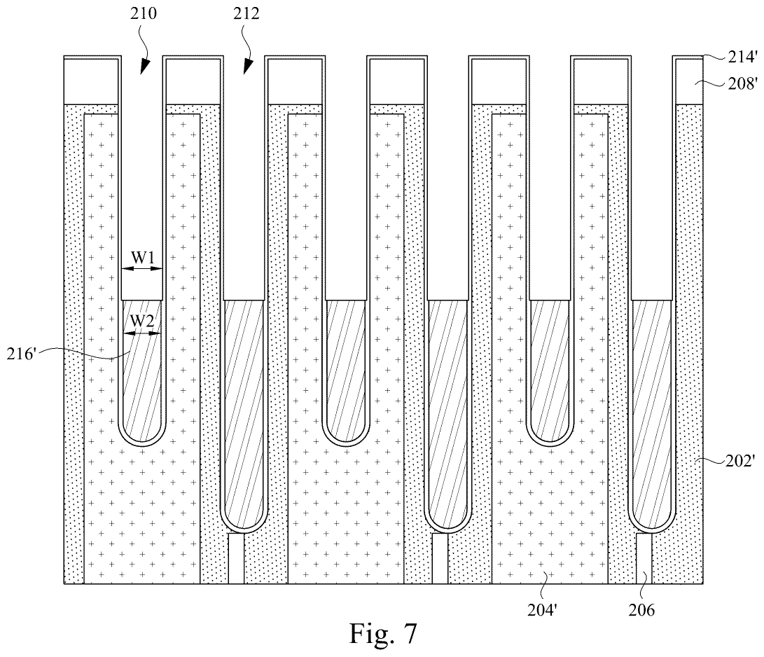

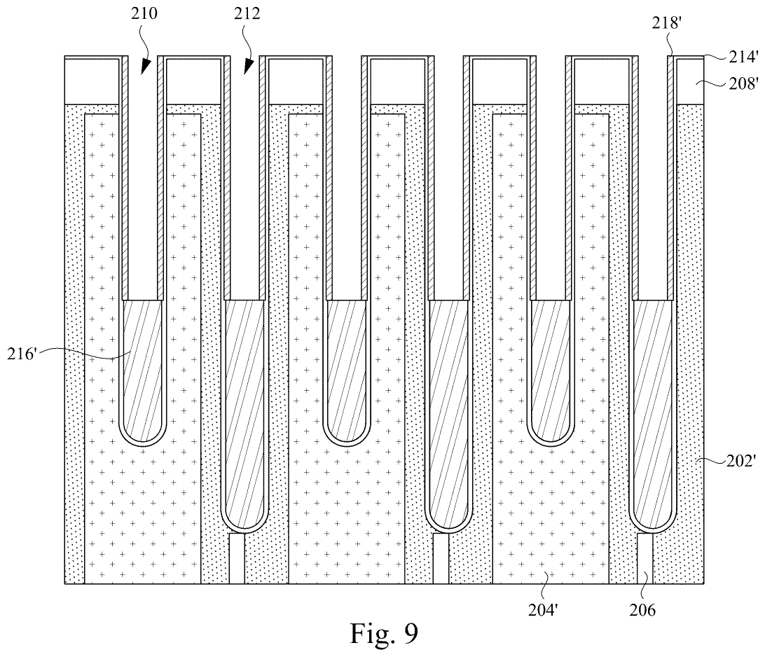

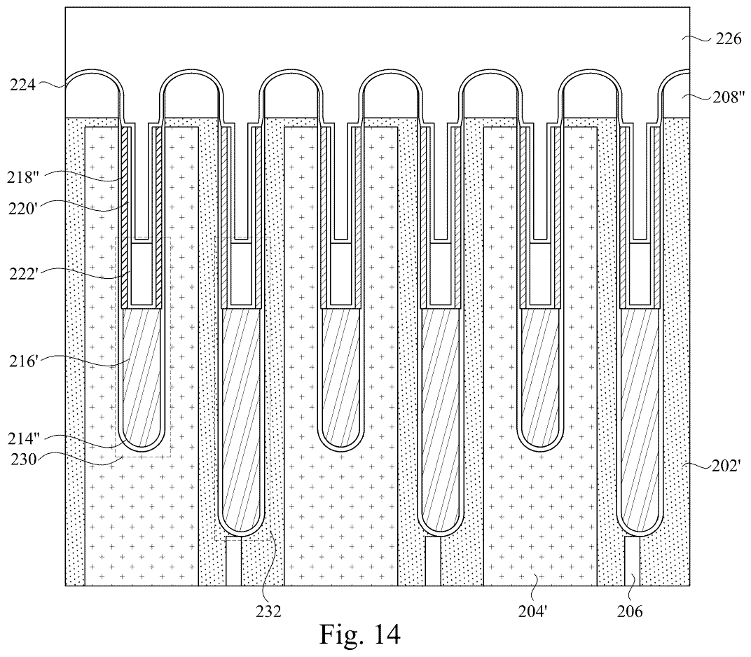

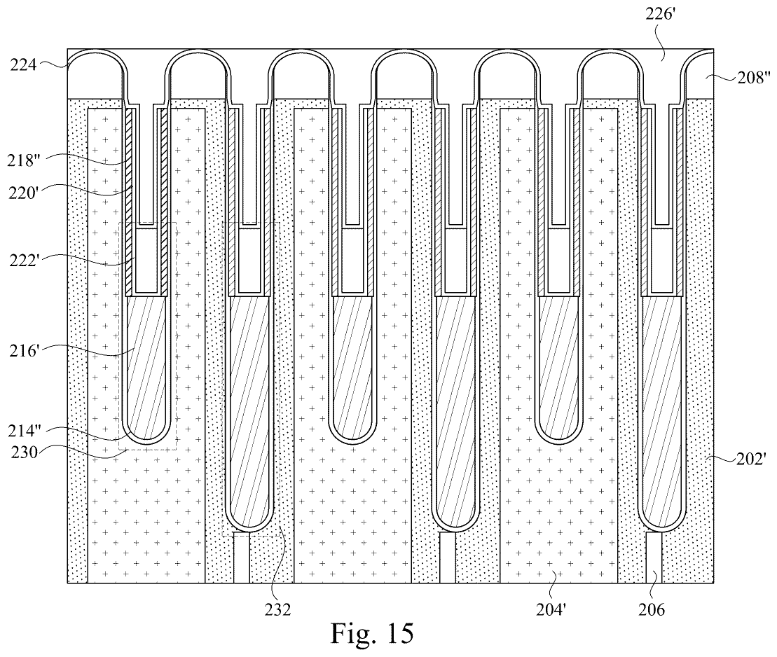

FIG. 1A is a flow diagram of a method 100 of forming a semiconductor structure, in accordance with various embodiments. The method 100 includes operations 110, 120, 130, 140, 150, and 160. FIGS. 2-16 are cross-sectional views illustrating intermediate stages of forming a semiconductor structure 234, in accordance with various embodiments of the present disclosure. Although a series of operations are used below to describe the method disclosed herein, an order of these operations or steps should not be construed as a limitation to the present disclosure. For example, some operations may be performed in a different order, and/or other steps may be performed at the same time. In addition, it is not necessary to perform all of the operations and/or features shown to achieve the embodiments of the present disclosure. In addition, each operations described herein may contain several sub-steps or actions.

As shown in FIGS. 1A and 2, the method 100 begins with operation 110. As shown FIG. 2, a semiconductor structure 200 is formed, in which the semiconductor structure 200 includes an oxide layer 202, a substrate 204, a plurality of hard mask structures 206, and a hard mask layer 208. The substrate 204 and the hard mask structures 206 are received, in which the substrate 204 has recesses to accommodate the hard mask structures 206. The oxide layer 202 covers the substrate 204 and the hard mask structures 206 and fills the recesses of the substrate 204. In some embodiments, the oxide layer 202 is formed by a thermal oxidation process. The hard mask layer 208 is deposited on the oxide layer 202, the substrate 204, and the hard mask structures 206. As shown in FIG. 2, the hard mask structures 206 are embedded in the oxide layer 202. In some embodiments, the hard mask layer 208 is in contact with the oxide layer 202. In some embodiments, the oxide layer 202 includes silicon dioxide (SiO₂). In some embodiments, the substrate 204 is a semiconductor substrate. In some embodiments, the substrate 204 include a silicon (Si) substrate, a substrate formed of a material including Si, a Si on insulator (SOI) substrate, or other types of semiconductor material. In some embodiments, the hard mask structures 206 and the hard mask layer 208 are respectively blocking structures and a blocking layer. In some embodiments, the hard mask structures 206 and the hard mask layer 208 include an insulating nitride. In some embodiments, the hard mask structures 206 and the hard mask layer 208 independently include silicon nitride (Si₃N₄), silicon oxynitride (SiON), or a combination thereof. In some embodiments, materials of the hard mask structures 206 and materials of the hard mask layer 208 are the same. In some embodiments, materials of the hard mask structures 206 and materials of the hard mask layer 208 are different. In some embodiments, the top surface of the substrate 204 is higher than the top surfaces of the hard mask structures 206.

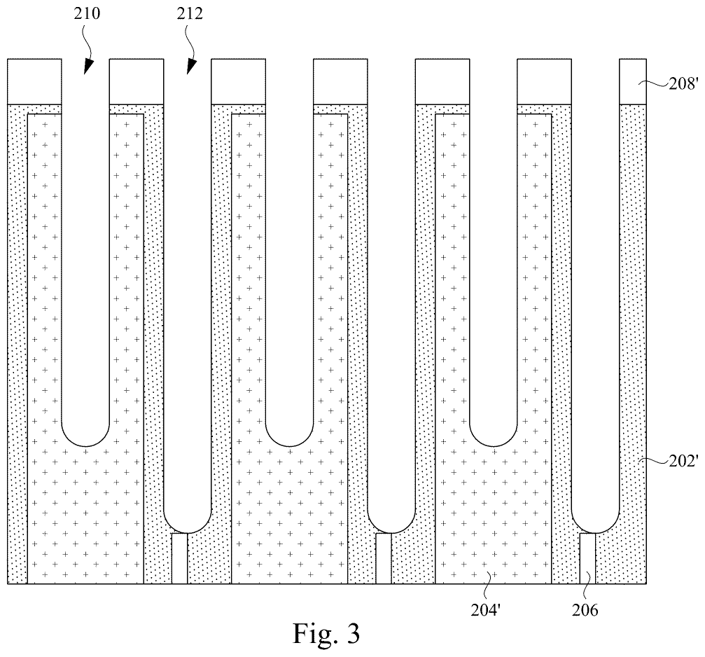

As shown in FIGS. 1A and 3, in operation 120, first trenches 210 and second trenches 212 are formed in the substrate 204 and the oxide layer 202, respectively. In some embodiments, the second trenches 212 are formed in the substrate 204. In some embodiments, the first trenches 210 and the second trenches 212 are formed by the etching process. In some embodiments, the first trenches 210 and the second trenches 212 are formed by dry etching process. In some embodiments, the first trenches 210 and the second trenches 212 are formed by etching the substrate 204, the oxide layer 202, and the hard mask layer 208, and an oxide layer 202′, a substrate 204′, and a hard mask layer 208′ are formed. In some embodiments, cross-sections of the first trenches 210 and the second trenches 212 are U-shaped. In some embodiments, top surfaces of the hard mask structures 206 are in contact with bottoms of the second trenches 212. In some embodiments, the first trenches 210 and the second trenches 212 are alternatively formed. In some embodiments, depths of the first trenches 210 are less than depths of the second trenches 212. The first trenches 210 and the second trenches 212 may be any number(s), e.g., one, two, three, four, five, etc.

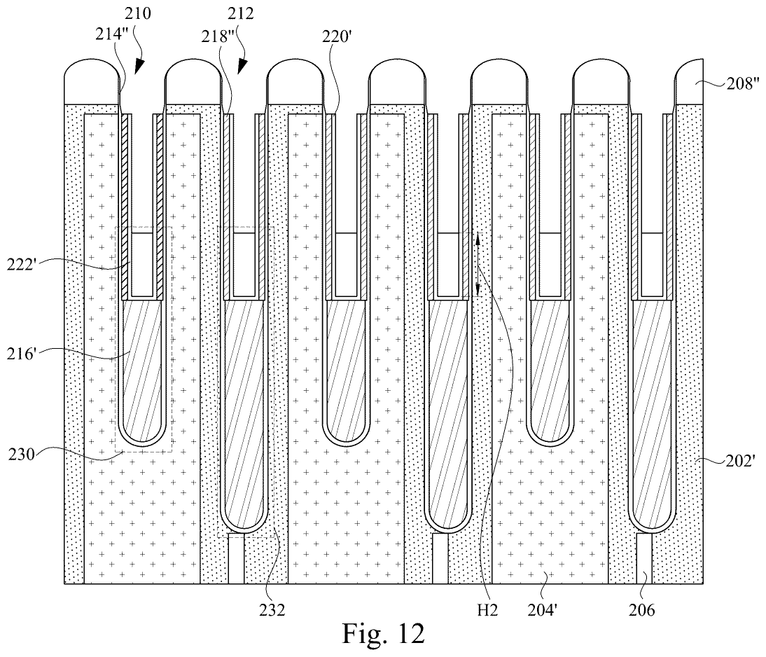

As shown in FIGS. 1A and 12, in operation 130, first gate structures 230 are formed in the first trenches 210, and second gate structures 232 are formed in the second trenches 212. The forming method of the first gate structures 230 formed in the first trenches 210 will be described in the followings. Please refer to the forming method of the first gate structures 230 formed in the first trenches 210 for the forming method of the second gate structures 232 formed in the second trenches 212. FIG. 1B is a flow diagram of a method of forming the first gate structures 230, in accordance with various embodiments. As shown in FIG. 1B, forming the first gate structures 230 in the first trenches 210 includes operations 131, 132, 133, 134, 135, 136, 137, and 138. The first gate structures 230 of the present disclosure have an effect of the mitigation of GIDL.

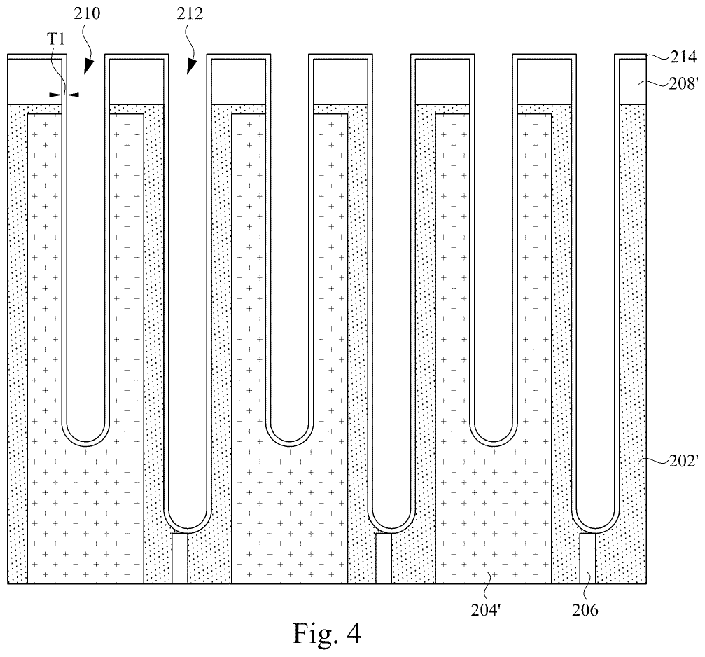

As shown in FIGS. 1B and 4, in operation 131, a first dielectric layer 214 is formed to cover inner surfaces of the first trenches 210. In some embodiments, the first dielectric layer 214 is formed by a deposition process, a thermal oxidation process, or a combination thereof. In some embodiments, the first dielectric layer 214 is formed by atomic layer deposition (ALD), in situ steam generation (ISSG), or a combination thereof. In some embodiments, the first dielectric layer 214 is deposited conformally on the inner surfaces of the first trenches 210. In some embodiments, the first dielectric layer 214 covers a top surface of the hard mask layer 208'. In some embodiments, the first dielectric layer 214 is in contact with the top surface of the hard mask layer 208′ and the inner surfaces of the first trenches 210. In some embodiments, the first dielectric layer 214 includes an oxide or a nitride, such as SiO₂, Si₃N₄, SiON, high-k materials, or combinations thereof, in which high-k materials may include hafnium oxide (HfO₂), silicon doped hafnium oxide (HSO), lanthanum oxide (La₂O₃), lanthanum aluminum oxide (LaAlO₃), zirconium oxide (ZrO₂), zirconium silicate oxide (ZrSiO₄), aluminum oxide (Al₂O₃), or combinations thereof. If the first dielectric layer 214 includes the aforementioned materials, the GIDL effects can be reduced. In some embodiments, a thickness T1 of the first dielectric layer 214 is between 2 nm and 3.8 nm, such as 2, 2.2, 2.4, 2.6, 2.8, 3, 3.2, 3.4, 3.6, or 3.8 nm. If the thickness of the first dielectric layer 214 is between 2 nm and 3.8 nm, the GIDL effects can be reduced. Forming the first dielectric layer 214 in the first trenches 210 can separate the gate and the drain formed subsequently, such that the electric field strength between the gate and the drain formed subsequently decreases. Therefore, the GIDL effects can be reduced.

As shown in FIGS. 1B, 5, and 6, in operation 132, first gate electrodes 216′ are formed in the first trenches 210 and on the first dielectric layer 214. In some embodiments, the operation 132 further includes depositing a first conductive layer 216 on the first dielectric layer 214 and filling in the first trenches 210; and etching the first conductive layer 216 to form the first gate electrodes 216′ in the first trenches 210 and on the first dielectric layer 214. In some embodiments, the first conductive layer 216 is deposited by chemical vapor deposition (CVD) process, physical vapor deposition (PVD) process, atomic layer deposition (ALD) process, low pressure CVD (LPCVD) process, another deposition process, or any suitable combination thereof. In some embodiments, the first conductive layer 216 is etched by the dry etching process. In some embodiments, a work function of the first gate electrode 216′ is higher than 4.3 eV. In some embodiments, the work function of the first gate electrode 216′ is between 4.3 eV and 5 eV, such as 4.3, 4.4, 4.5, 4.6, 4.7, 4.8, 4.9, or 5 eV. In some embodiments, the first conductive layer 216 includes metal or metal nitride, such as titanium nitride (TiN), titanium nitride (Ti), tungsten (W), tungsten nitride (WN), tantalum (Ta), tantalum nitride (TaN), or combinations thereof. In some embodiments, a height H1 of each first gate electrodes 216′ is between 80 nm and 90 nm, such as 80, 81, 82, 83, 84, 85, 86, 87, 88, 89, or 90 nm. If the height H1 of each first gate electrodes 216′ is between 80 nm and 90 nm, the leakage phenomenon decreases (GIDL decreases), and the fast signal transmission speed of the word line (gate structure) formed subsequently is maintained simultaneously.

As shown in FIG. 1B, and 7, in operation 133, exposed portions of the first dielectric layer 214 is etched to form a first dielectric layer 214′. In some embodiments, the exposed portions of the first dielectric layer 214 are the first dielectric layer 214 positioned on sidewalls of the first trenches 210 on the first gate electrodes 216′ and on top surfaces of the hard mask layer 208′. In some embodiments, the exposed portion of the first dielectric layer 214 is etched by the wet etching process. The exposed portion of the first dielectric layer 214 is etched to clean the first conductive layer 216 remaining on the sidewalls of the first trenches 210 on the first gate electrodes 216′ and on the top surfaces of the hard mask layer 208. In some embodiments, a width W1 of each of the first trenches 210 is greater than a width W2 of each of the first gate electrodes 216′.

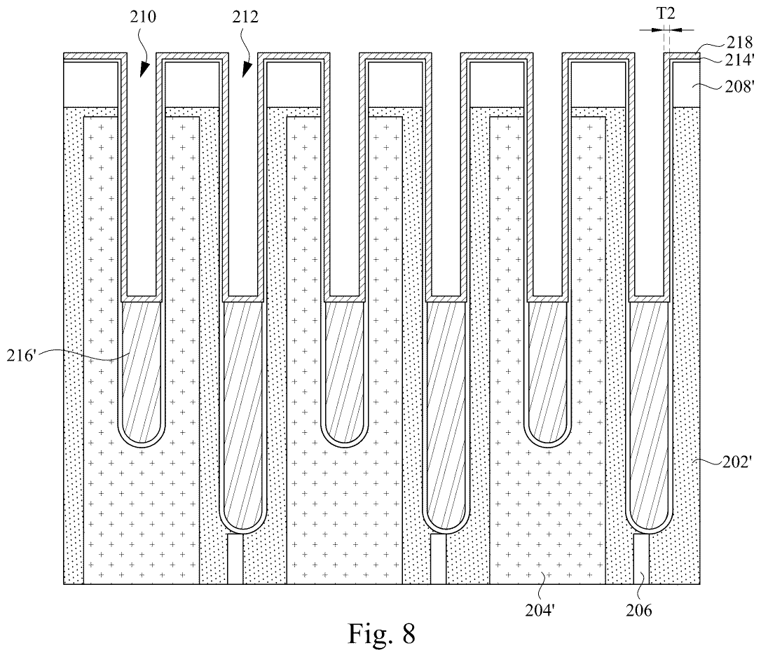

As shown in FIGS. 1B and 8, in operation 134, a second dielectric layer 218 is deposited in the first trenches 210 to cover the first gate electrodes 216′ and the first dielectric layer 214′. In some embodiments, the second dielectric layer 218 is deposited by the ALD process or any suitable processes. In some embodiments, the second dielectric layer 218 is in contact with the exposed portion of the first dielectric layer 214′ and the top surfaces of the first gate electrodes 216′. In some embodiments, the second dielectric layer 218 is deposited conformally in the first trenches 210 to cover the first gate electrodes 216′ and the first dielectric layer 214′. In some embodiments, the second dielectric layer 218 includes an oxides or a nitride, such as SiO₂, Si₃N₄, SiON, high-k materials, or combinations thereof, in which the high-k materials may include HfO₂, HSO, La₂O₃, LaAlO₃, ZrO₂, ZrSiO₄, Al₂O₃, or combinations thereof. If the second dielectric layer 218 includes the aforementioned materials, the GIDL effects can be reduced. In some embodiments, a material of the second dielectric layer 218 is same as a material of the first dielectric layer 214. In some embodiments, the material of the second dielectric layer 218 is different from the material of the first dielectric layer 214. In some embodiments, a thickness T2 of the second dielectric layer 218 is greater than the thickness T1 of the first dielectric layer 214 (shown in FIG. 4). In some embodiments, the thickness T2 of the second dielectric layer 218 is between 3 nm and 7 nm, such as 3, 4, 5, 6, or 7 nm. If the thickness T2 of the second dielectric layer 218 is between 3 nm and 7 nm, the GIDL effects can be reduced.

As shown in FIGS. 1B, 8, and 9, in operation 135, portions of the second dielectric layer 218 are etched to expose the first gate electrodes 216′. In some embodiments, portions of the second dielectric layer 218 are horizontal portions of the second dielectric layer 218. In some embodiments, portions of the second dielectric layer 218 are etched to form second dielectric layers 218′ covering sidewalls of the first dielectric layers 214′. In some embodiments, portions of the second dielectric layer 218 are etched by the dry etching process. In some embodiments, portions of the second dielectric layer 218 are etched to expose the top surfaces of the first gate electrodes 216′. Forming the second dielectric layers 218′ covering the sidewalls of the first dielectric layers 214′ can decrease the electric field strength between the gate and the drain formed subsequently. Thus, the GIDL can be reduced.

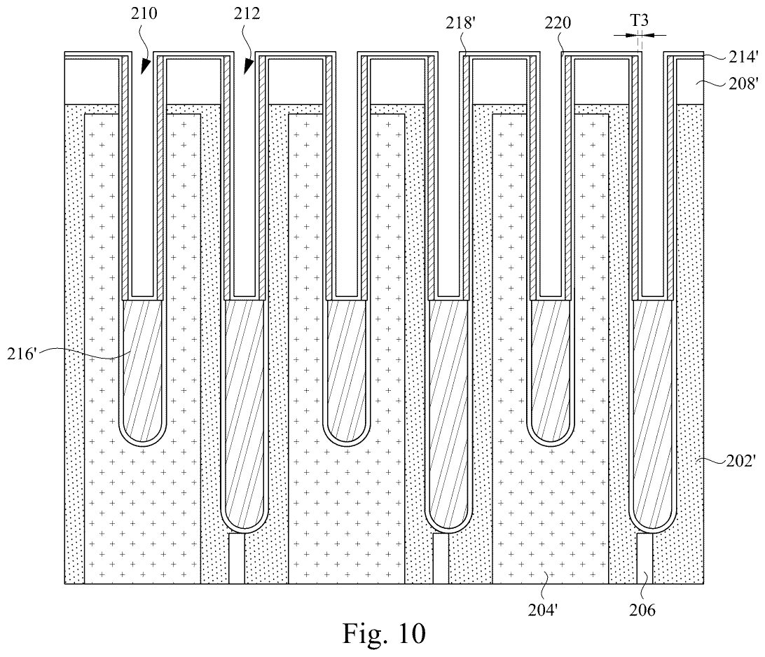

As shown in FIGS. 1B and 10, in operation 136, a third dielectric layer 220 is deposited in the first trenches 210 to cover the first gate electrodes 216′ and the second dielectric layers 218′. In some embodiments, the third dielectric layer 220 is deposited conformally in the first trenches 210 to cover the first gate electrodes 216′ and the second dielectric layers 218′. In some embodiments, the third dielectric layer 220 covers the top surfaces of the first gate electrodes 216′. In some embodiments, the third dielectric layer 220 is in contact with the top surfaces of first gate electrodes 216′ and a top surface of the first dielectric layer 214′. In some embodiments, the third dielectric layer 220 is deposited by the ALD process or any suitable processes. In some embodiments, the third dielectric layer 220 includes an oxide or a nitride, such as SiO₂, Si₃N₄, SiON, high-k materials, or combinations thereof, in which the high-k materials may include HfO₂, HSO, La₂O₃, LaAlO₃, ZrO₂, ZrSiO₄, Al₂O₃, or combinations thereof. If the third dielectric layer 220 includes the aforementioned materials, the GIDL effects can be reduced. In some embodiments, a material of the third dielectric layer 220 is same as the material of the first dielectric layer 214 and the material of the second dielectric layer 218. In some embodiments, the material of the third dielectric layer 220 is different from the material of the first dielectric layer 214 and the material of the second dielectric layer 218. In some embodiments, a thickness T3 of each of the third dielectric layer 220 is less than the thickness T2 of each of the second dielectric layer 218 (shown in FIG. 8). In some embodiments, a thickness T3 of the third dielectric layer 220 is between 0.1 nm and 3 nm, such as 0.1, 0.2, 0.4, 0.6, 0.8, 1, 1.2, 1.4, 1.6, 1.8, 2, 2.2, 2.4, 2.6, 2.8, or 3 nm. If the thickness T3 of the third dielectric layer 220 is between 0.1 nm and 3 nm, the GIDL effects can be reduced. After forming the second dielectric layers 218′ and the third dielectric layer 220, thick dielectric layers (i.e., the second dielectric layers 218′ and the third dielectric layer 220) are formed at the sidewalls of the first trenches 210 on the first gate electrodes 216′ (the thicknesses of the thick dielectric layers are between 4 nm and 9 nm, such as 4, 5, 6, 7, 8, or 9 nm), and a thin dielectric layer (i.e., the third dielectric layer 220) is formed on the top surfaces of the first gate electrodes 216′ (the thickness of the thin dielectric layer is between 0.1 nm and 3 nm, such as 0.1, 0.2, 0.4, 0.6, 0.8, 1, 1.2, 1.4, 1.6, 1.8, 2, 2.2, 2.4, 2.6, 2.8, or 3 nm). The formation of the gate structures with the features mentioned above (thick and thin dielectric layers) by aforementioned forming method 100 may cause the GIDL decreases and the fast signal transmission speed of the gate (word line) is maintained.

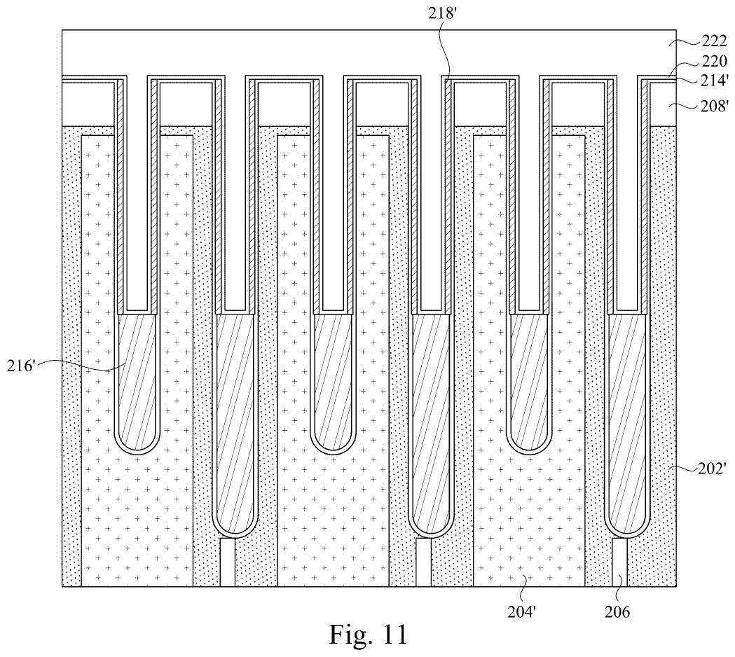

As shown in FIGS. 1B and 11, in operation 137, a second conductive layer 222 is deposited on the first dielectric layer 214′ and fills the first trenches 210. In some embodiments, the second conductive layer 222 is deposited by CVD process, PVD process, ALD process, LPCVD process, another deposition process, or any suitable combination thereof. In some embodiments, a material of the second conductive layer 222 is different from the material of the first conductive layer 216. In some embodiments, the second conductive layer 222 includes doped polycrystalline silicon, for example, polycrystalline silicon doped with N-type dopants. In some embodiments, the N-type dopants include phosphorous (P), arsenic (As), or a combination thereof. Polycrystalline silicon doped with P increases the conductivity of the polycrystalline silicon.

As shown in FIGS. 1B, 11, and 12, in operation 138, a plurality of second gate electrodes 222′ are formed in the first trenches 210 and on third dielectric layers 220′. In some embodiments, top surfaces of the hard mask layer 208′, the first dielectric layers 214′ on the top surfaces and the sidewalls of the hard mask layer 208′, the second dielectric layers 218′ on the sidewalls of the hard mask layer 208′, the third dielectric layer 220 on the top surfaces and the sidewalls of the hard mask layer 208′ (shown in FIG. 11) are etched to form hard mask layers 208″, first dielectric layers 214″, second dielectric layers 218″, the third dielectric layers 220′. In some embodiments, the second gate electrodes 222′ are formed by etching the second conductive layer 222, in which the second conductive layer 222 is etched by the dry etching process. In some embodiments, a work function of the second gate electrode 222′ is different from the work function of the first gate electrode 216′. In some embodiments, the work function of the second gate electrodes 222′ are less than the work function of the first gate electrodes 216′. In some embodiments, the work function of the second gate electrodes 222′ is lower than 4.5 eV, such as 4, 4.1, 4.2, 4.3, 4.4, or 4.5 eV. Due to different materials used in the first gate electrodes 216′ and the second gate electrodes 222′, the first gate electrodes 216′ and the second gate electrodes 222′ include different work functions. The first gate electrodes 216′ and the second gate electrodes 222′ with different work functions cause different electric field distribution near the word line (gate structure) during subsequent operations, such as reading and writing of the word line, such that the GIDL effect can be efficiently controlled. In some embodiments, a height H2 of each second gate electrodes 222′ is between 50 nm and 60 nm, such as 50, 51, 52, 53, 54, 55, 56, 57, 58, 59, or 60 nm. If the height H2 of each second gate electrodes 222′ is between 50 nm and 60 nm, the leakage phenomenon decreases (GIDL decreases) and the fast signal transmission speed of the word line (gate structure) is maintained simultaneously. After performing the operations 131-138, the first gate structures 230 are formed, as shown in FIG. 12.

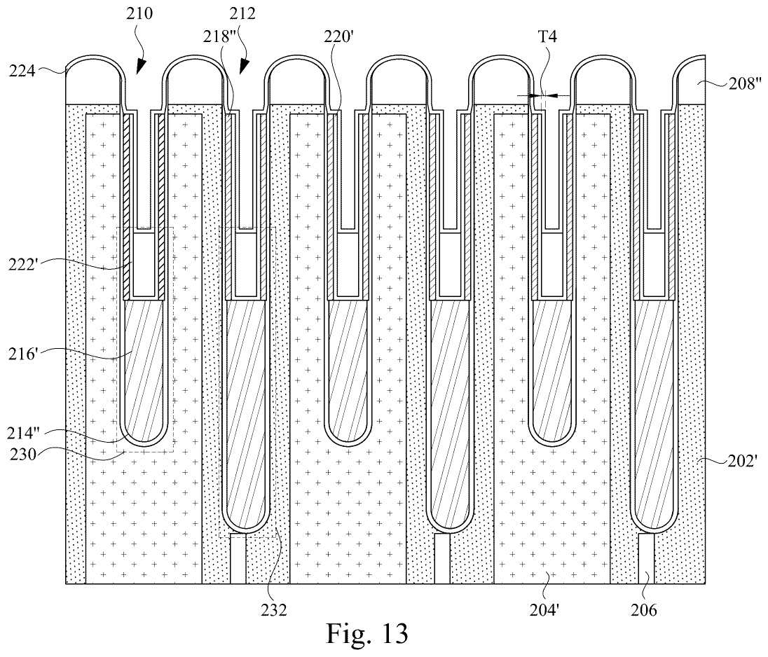

As shown in FIGS. 1A and 13, in operation 140, a fourth dielectric layer 224 is deposited to cover the first gate structures 230 in the first trenches 210 and the second gate structures 232 in the second trenches 212. In some embodiments, the fourth dielectric layer 224 is deposited to cover the second gate electrodes 222′, the second dielectric layers 218″, the third dielectric layers 220′, the first dielectric layers 214″, and the hard mask layers 208″. In some embodiments, the fourth dielectric layer 224 is deposited by ALD process or any suitable combination thereof. In some embodiments, the fourth dielectric layer 224 is deposited conformally to cover the second gate electrodes 222′, the second dielectric layers 218″, the third dielectric layers 220′, the first dielectric layers 214″, and the hard mask layers 208″. In some embodiments, the fourth dielectric layer 224 includes an oxide or a nitride, such as SiO₂, Si₃N₄, SiON, high-k materials, or combinations thereof, in which the high-k materials may include HfO₂, HSO, La₂O₃, LaAlO₃, ZrO₂, ZrSiO₄, Al₂O₃, or combinations thereof. In some embodiments, a material of the fourth dielectric layer 224 is same as the material of the first dielectric layer 214, the material of the second dielectric layer 218, and the material of the third dielectric layer 220. In some embodiments, the material of the fourth dielectric layer 224 is different from the material of the first dielectric layer 214, the material of the second dielectric layer 218, and the material of the third dielectric layer 220. In some embodiments, a thickness T4 of the fourth dielectric layer 224 is between 0.1 nm and 3 nm, such as 0.1, 0.2, 0.4, 0.6, 0.8, 1, 1.2, 1.4, 1.6, 1.8, 2, 2.2, 2.4, 2.6, 2.8, or 3 nm.

As shown in FIGS. 1A, 13, 14, and 15, in operation 150, capping layers 226′ are formed in the first trenches 210 and the second trenches 212 and on the fourth dielectric layer 224. In some embodiments, the capping layers 226′ are formed on the second gate electrodes 222′. In some embodiments, the operation 150 further includes depositing a dielectric layer 226 in the first trenches 210 and the second trenches 212 and on the fourth dielectric layer 224; and planarizing the dielectric layer 226 to form the capping layers 226′ in the first trenches 210 and the second trenches 212 and on the fourth dielectric layer 224 to fill the first trenches 210 the second trenches 212. In some embodiments, the dielectric layer 226 is deposited by CVD process, PVD process, ALD process, LPCVD process, another deposition process, or any suitable combination thereof. In some embodiments, the capping layers 226′ are planarized by chemical-mechanical polishing (CMP). In some embodiments, the capping layers 226′ include dielectric materials (an oxide, a nitride, or a combination thereof), such as SiO₂, Si₃N₄, SiON, or combinations thereof.

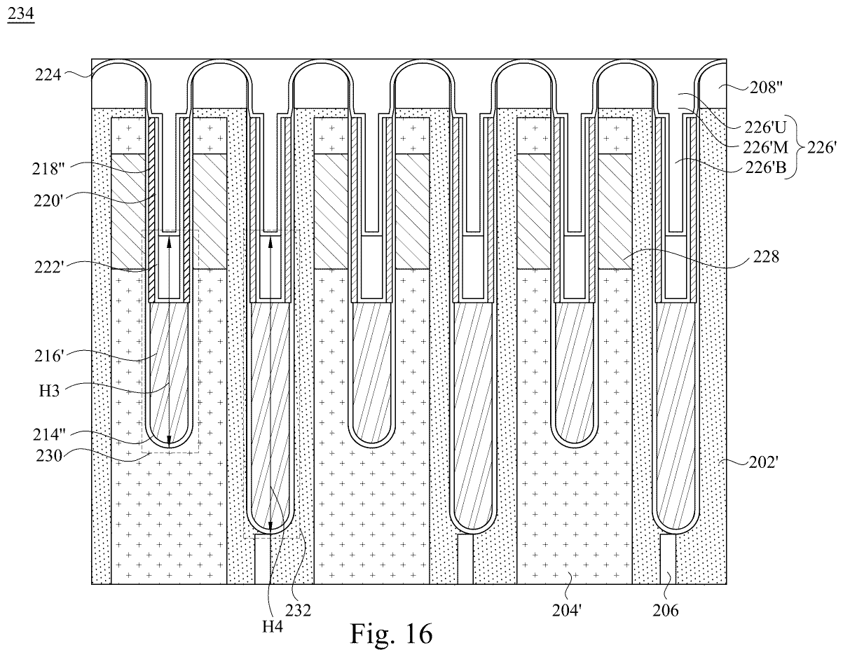

As shown in FIGS. 1A and 16, in operation 160, a plurality of doped regions 228 are formed in the substrate 204′ and on both sides of the first gate structures 230 and the second gate structures 232. In some embodiments, the doped regions 228 are formed on both sides of the second gate electrodes 222′. In some embodiments, the doped regions 228 are source/drain regions. In some embodiments, the doped regions 228 are formed by ion implantation process. In some embodiments, the doped regions 228 are doped with positive type dopants, such as boron (B), gallium (Ga), or the like. In some embodiments, the doped regions 228 are doped with negative type dopants, such as P, As, or the like.

As shown in FIG. 16, the present disclosure provides the semiconductor structure 234. As shown in FIG. 16, the semiconductor structure 234 includes the substrate 204′, the oxide layer 202′, the hard mask structures 206, the hard mask layer 208″, the first gate structures 230, the second gate structures 232, the fourth dielectric layer 224, the capping layers 226′, and the doped regions 228. In some embodiments, the recessed portions of the substrate 204 form U-shapes in cross-sections. The oxide layer 202′ is formed in the substrate 204′. In some embodiments, the oxide layer 202′ covers the outer sidewalls and the top surface of the substrate 204′. The hard mask structures 206 are disposed in the oxide layer 202′. The hard mask layer 208″ is formed on the top surfaces of the oxide layer 202′ and the substrate 204′. In some embodiments, the hard mask layer 208″ is in contact with the top surface of the oxide layer 202′. In some embodiments, the cross-section of the hard mask layer 208″ is formed rectangular at the bottom portion and formed semi-circle at the upper portion. In some embodiments, the bottom portion of the hard mask layer 208″ is in contact with the top surface of the oxide layer 202′.

As shown in FIG. 16, the first gate structures 230 are embedded in the substrate 204′ and the second gate structures 232 are embedded in the oxide layer 202′. In some embodiments, heights H3 of the first gate structures 230 are less than heights H4 of the second gate structures 232. In some embodiments, outer side contours of cross-sections of the first gate structures 230 and the second gate structures 232 are U-shaped. In some embodiments, the first gate structures 230 and the second gate structures 232 are alternatively formed.

As shown in FIG. 16, each first gate structures 230 includes a first gate electrode 216′, a second gate electrode 222′, a first dielectric layer 214″, second dielectric layers 218″, and a third dielectric layer 220′. The following will be described with one first gate structure 230. In some embodiments, an outer side contour of a cross-section of the first gate electrode 216′ is formed in a U-shaped. In some embodiments, a top surface of the first gate electrode 216′ is substantially flat. The second gate electrode 222′ is on the first gate electrode 216′. In some embodiments, an outer side contour of a cross-section of the second gate electrode 222′ is formed in a rectangular shape. In some embodiments, a width and a height of the second gate electrode 222′ are respectively less than a width and a height of the first gate electrode 216′.

Continually referring to FIG. 16, the first dielectric layer 214″ is disposed between the substrate 204′ and the first gate electrode 216′ and between the substrate 204′ and the second gate electrode 222′. In some embodiments, the first dielectric layer 214′ covers the outer surface of the first gate electrode 216′. In some embodiments, the first dielectric layer 214″ is in contact with the outer surface of the first gate electrode 216′. In some embodiments, the first dielectric layer 214″ is in contact with the substrate 204′. In some embodiments, a cross-section of the first dielectric layer 214″ is formed in a U-shaped. In some embodiments, a width of the first dielectric layer 214″ between the substrate 204′ and the first gate electrode 216′ is greater than a width of the first dielectric layer 214″ between the substrate 204′ and the second gate electrode 222′. In some embodiments, a cross-section of the first dielectric layer 214″ has a stair shape, in which the stair shape is on the sidewalls of the first gate electrode 216′ and the second gate electrode 222′. In some embodiments, the thickness of the first dielectric layer 214″ at two sides of the second gate electrode 222′ is between 1 nm and 4.5 nm, such as 1, 1.5, 2, 2.5, 3, 3.5, 4, or 4.5 nm.

Continually referring to FIG. 16, the second dielectric layers 218″ are disposed between the first dielectric layer 214″ and the second gate electrode 222′. In some embodiments, the second dielectric layers 218″ are in contact with the first dielectric layer 214″. In some embodiments, the second dielectric layers 218″ cover sidewalls of the second gate electrode 222′. In some embodiments, the second dielectric layers 218″ cover a portion of the first gate electrode 216′. In some embodiments, the second dielectric layers 218″ cover outer sides of the top surface of the first gate electrode 216′. In some embodiments, the materials of the second dielectric layers 218″ are different from a material of the first dielectric layer 214″. In some embodiments, the materials of the second dielectric layers 218″ are same as the material of the first dielectric layer 214″.

Continually referring to FIG. 16, the third dielectric layer 220′ is disposed between the second dielectric layers 218″ and the second gate electrode 222′ and between the first gate electrode 216′ and the second gate electrode 222′. In some embodiments, the third dielectric layer 220′ covers sidewalls of the second gate electrode 222′. In some embodiments, the third dielectric layer 220′ is in contact with inner surfaces of the second dielectric layers 218″, the sidewalls and the bottom of the second gate electrode 222′, and the middle portion of the top surface of the first gate electrode 216′. In some embodiments, a material of the third dielectric layer 220′ is different from the material of the second dielectric layers 218″ and the material of the first dielectric layer 214″. In some embodiments, the material of the third dielectric layer 220′ is same as the material of the second dielectric layers 218″ and the material of the first dielectric layer 214″. In some embodiments, the first dielectric layer 214″, the second dielectric layers 218″, and the third dielectric layer 220′ independently include an oxide or a nitride, such as SiO₂, Si₃N₄, SiON, high-k materials, or combinations thereof, in which high-k materials include HfO₂, HSO, La₂O₃, LaAlO₃, ZrO₂, ZrSiO₄, Al₂O₃, or combinations thereof. In some embodiments, the thicknesses of the second dielectric layers 218″ are greater than the thickness of the third dielectric layer 220′ and the thickness of the first dielectric layer 214″. In some embodiments, the thickness of the first dielectric layer 214″ is between 2 nm and 3.8 nm (such as 2, 2.2, 2.4, 2.6, 2.8, 3, 3.2, 3.4, 3.6, and 3.8 nm), the thickness of the second dielectric layers 218″ are between 3 nm and 7 nm (such as 3, 4, 5, 6, or 7 nm), and the thickness of the third dielectric layer 220′ is between 0.1 nm and 3 nm (such as 0.1, 0.2, 0.4, 0.6, 0.8, 1, 1.2, 1.4, 1.6, 1.8, 2, 2.2, 2.4, 2.6, 2.8, or 3 nm). The thick dielectric layers (the second dielectric layers 218″ and the third dielectric layer 220′) formed on the sidewalls of the second gate electrode 222′, and a thin dielectric layer (the third dielectric layer 220′) formed between the first gate electrode 216′ and the second gate electrode 222′ cause the decreased GIDL and maintains a fast signal transmission speed of the gate structure (word line).

As shown in FIG. 16, each second gate structure 232 includes a first gate electrode 216′, a second gate electrode 222′, a first dielectric layer 214″, second dielectric layers 218″, and a third dielectric layer 220′. In some embodiments, heights of the first gate electrodes 216′ of the second gate structures 232 are greater than heights of the first gate electrodes 216′ of the first gate structures 230. Refer to the aforementioned embodiments (i.e., the configurations, the shapes, and the sizes of every component in the first gate structures 230) and the effects of the first gate structures 230 for the embodiments (i.e., the configurations, the shapes, and the sizes of every component in the first gate structures 230) and the effects of the second gate structures 232.

Refer to FIG. 16. In some embodiments, the first dielectric layers 214″, the second dielectric layers 218″, and the third dielectric layers 220′ also form on the first gate structures 230 and the second gate structures 232. In some embodiments, the first dielectric layers 214″, the second dielectric layers 218″, and the third dielectric layers 220′ on the first gate structures 230 and the second gate structures 232 extend along the first dielectric layers 214″, the second dielectric layers 218″, and the third dielectric layers 220′ in the first gate structures 230 and the second gate structures 232. The following will be described the first dielectric layers 214″, the second dielectric layers 218″, and the third dielectric layers 220′ on the first gate structures 230 and the second gate structures 232. In some embodiments, the first dielectric layers 214″ are in contact with the hard mask layer 208″. In some embodiments, the thicknesses of the upper portion of the first dielectric layers 214″ gradually decrease from the position aligned with the top surfaces of the substrate 204′ to the position aligned with the bottom surfaces of the hard mask layers 208″. In some embodiments, the first dielectric layers 214″ on the first gate structures 230 are in contact with the sidewalls of the oxide layer 202′ covering the top surfaces of the substrate 204′. In some embodiments, the thicknesses of the first dielectric layers 214″ on sidewalls of the hard mask layers 208″ are between 0.5 nm and 3.5 nm, such as 0.5, 1, 1.5, 2, 2.5, 3, or 3.5 nm. In some embodiments, top surfaces of the second dielectric layers 218″ and the third dielectric layers 220′ are substantially aligned with the top surface of the substrate 204′. In some embodiments, top surfaces of the second dielectric layers 218″ and the third dielectric layers 220′ are lower than the top surface of the substrate 204′.

Continually referring to FIG. 16, the capping layers 226′ are disposed on the first gate structures 230 and the second gate structures 232, in which each capping layers 226′ includes a below portion 226′B, a middle portion 226′M, and an upper portion 226′U. In some embodiments, the capping layers 226′ are disposed on the second gate electrodes 222′. In some embodiments, the below portions 226′B of the capping layers 226′ are surrounded by the third dielectric layers 220′, the second dielectric layers 218″, the first dielectric layers 214″, and the substrate 204′. In some embodiments, the middle portions 226′M of the capping layers 226′ are surrounded by the oxides layer 202′ on the top surfaces of the substrate 204′. In some embodiments, the upper portions of the capping layers 226′ are surrounded by the hard mask layers 208″. In some embodiments, widths of the upper portions 226′U of the capping layers 226′ are greater than widths of the middle portions 226′M and the below portions 226′B of the capping layers 226′. In some embodiments, widths of the middle portions 226′M of the capping layers 226′ are greater than widths of the below portions 226′B of the capping layers 226′.

Continually referring to FIG. 16, the fourth dielectric layer 224 is disposed between the third dielectric layers 220′ and the capping layers 226′ and between the second gate electrodes 222′ and the below portions 226′B of the capping layers 226′. In some embodiments, the fourth dielectric layer 224 is disposed between the first dielectric layers 214″ and the middle portions 226′M of the capping layers 226′ and between the top surfaces of the second dielectric layers 218″, the third dielectric layers 220′ and the middle portions 226′M of the capping layers 226′. In some embodiments, the fourth dielectric layers 224 are disposed between the first dielectric layers 214″ and the upper portions 226′U of the capping layers 226′ and between the hard mask layers 208″ and the upper portions 226′U of the capping layers 226′. The doped regions 228 are disposed in the substrate 204′ and on both sides of the second gate electrodes 222′ and the below portions 226′B of the capping layers 226′. Refer to the aforementioned embodiments (i.e., the materials, the dimensions, and the sizes of every component) and the corresponding effects described in the manufacturing method 100 of the semiconductor structure 234 for the embodiments (i.e., the materials, the dimensions, and the sizes of every component) and the corresponding effects of the semiconductor structure 234.

In summary, the present disclosure provides a semiconductor structure and a manufacturing method thereof. The semiconductor structure having a gate structure with a thick dielectric layer on the sidewalls of the second gate electrode and a thin dielectric layer between the first and second gate electrodes can be formed through the manufacturing method of the semiconductor structure of the present disclosure. Therefore, the GIDL is decreased and a fast signal transmission speed of the gate (word line) is maintained.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
forming a first trench in a substrate; and
forming a first gate structure in the first trench, comprising:
forming a first dielectric layer to cover an inner surface of the first trench;
forming a first gate electrode in the first trench and on the first dielectric layer;
depositing a second dielectric layer in the first trench to cover the first gate electrode and the first dielectric layer;
etching a portion of the second dielectric layer to expose the first gate electrode;
depositing a third dielectric layer in the first trench to cover the first gate electrode and the second dielectric layer; and
forming a second gate electrode in the first trench and on the third dielectric layer.

2. The method of claim 1, further comprising:
after forming the second gate electrode in the first trench, forming a plurality of doped regions in the substrate and on both sides of the second gate electrode.

3. The method of claim 1, wherein a thickness of the second dielectric layer is greater than a thickness of the third dielectric layer and a thickness of the first dielectric layer.

4. The method of claim 1, wherein a thickness of the first dielectric layer is between 2 nm and 3.8 nm, a thickness of the second dielectric layer is between 3 nm and 7 nm, and a thickness of the third dielectric layer is between 0.1 nm and 3 nm.

5. The method of claim 1, wherein a work function of the first gate electrode is different from a work function of the second gate electrode.

6. The method of claim 1, further comprising:
after forming the second gate electrode in the first trench, forming a capping layer in the first trench and on the second gate electrode to fill the first trench.

7. The method of claim 6, further comprising:
before forming the capping layer in the first trench and on the second gate electrode to fill the first trench, depositing a fourth dielectric layer to cover the second gate electrode and the second dielectric layer.

8. The method of claim 7, wherein a thickness of the fourth dielectric layer is between 0.1 nm and 3 nm.

9. The method of claim 1, wherein a height of the first gate electrode is between 80 nm and 90 nm, and a height of the second gate electrode is between 50 nm and 60 nm.

10. The method of claim 1, further comprising:
forming a second trench in an oxide layer in the substrate, wherein forming the second trench in the oxide layer in the substrate and forming the first trench in the substrate are performed simultaneously; and
forming a second gate structure in the second trench, wherein forming the second gate structure in the second trench and forming the first gate structure in the first trench are performed simultaneously.

11. A semiconductor structure, comprising:
a substrate; and
a gate structure embedded in the substrate, comprising;
a first gate electrode;
a second gate electrode on the first gate electrode;
a first dielectric layer disposed between the substrate and the first gate electrode and between the substrate and the second gate electrode;
a second dielectric layer disposed between the first dielectric layer and the second gate electrode; and
a third dielectric layer disposed between the second dielectric layer and the second gate electrode and between the first gate electrode and the second gate electrode, wherein a material of the second dielectric layer is different from a material of the third dielectric layer.

12. The semiconductor structure of claim 11, wherein the material of the second dielectric layer is different from a material of the first dielectric layer.

13. The semiconductor structure of claim 11, wherein a thickness of the second dielectric layer is greater than a thickness of the third dielectric layer and a thickness of the first dielectric layer.

14. The semiconductor structure of claim 11, wherein a thickness of the first dielectric layer is between 2 nm and 3.8 nm, a thickness of the second dielectric layer is between 3 nm and 7 nm, and a thickness of the third dielectric layer is between 0.1 nm and 3 nm.

15. The semiconductor structure of claim 11, further comprising:
a plurality of doped regions disposed in the substrate and on both sides of the second gate electrode.

16. The semiconductor structure of claim 11, further comprising:
a capping layer disposed on the second gate electrode.

17. The semiconductor structure of claim 16, further comprising:
a fourth dielectric layer disposed between the third dielectric layer and the capping layer and between the second gate electrode and the capping layer.
